(19) United States
(12) Patent Application Publication
(10) Pub. No.: US 2017/0336447 A1
(43) Pub. Date: Nov. 23, 2017

(54) Systems and Methods for Determining a Load Condition of an Electric Device

(71) Applicant: V Square/R LLC, East Greenwich, RI (US)

(72) Inventors: Leo F. Valenti, East Greenwich, RI (US); James C. Daly, Ave Maria, FL (US); Thomas J. Valenti, Norht Kingstown, RI (US)

(21) Appl. No.: 15/595,193

(22) Filed: May 15, 2017

Related U.S. Application Data
(60) Provisional application No. 62/337,475, filed on May 17, 2016.

(51) Int. Cl. G01R 21/00; G01R 21/06; G01R 15/20; H01L 43/06; H02P 23/26

(52) U.S. Cl. CPC G01R 21/006; H01L 43/06; H02P 23/26; G01R 15/202; G01R 21/06

(57) ABSTRACT

In an example, a system for determining a power factor of an electric device powered by an alternating current (AC) power is described. The system includes a current sensor configured to: (i) remotely sense, at a position external to the electric device, a magnetic field formed by the AC power in the electric device, and (ii) determine, based on the sensed magnetic field, a current of the AC power. The system also includes a voltage sensor configured to, at a position external to the electric device, remotely measure a voltage of the AC power. The system further includes a computing device communicatively coupled to the current sensor and the voltage sensor, the computing device being configured to: (i) determine a phase delay between the current and the voltage, and (ii) determine, based on the phase delay, a power factor of the electric device.

### CROSS-REFERENCE TO RELATED APPLICATION

This application claims the benefit of U.S. Provisional Application No. 62/337,475, filed May 17, 2016, the contents of which is hereby incorporated by reference in its entirety.

### FIELD

The present disclosure generally relates to systems and methods for determining a load condition of an electric device, and more particularly to systems and methods for determining a power factor of an electric device.

### BACKGROUND

More than half of all electrical energy is consumed by induction motors. A substantial amount of the consumed electrical energy is wasted. For example, an induction motor is inefficient when it is not sufficiently loaded. In some instances, this occurs when designers (out of caution) prescribe a larger motor than is necessary or, in other instances, when motors run on idle for long periods of time and only periodically deliver power.

### SUMMARY

In an example, a system for determining a power factor of an electric device powered by an alternating current (AC) power is described. The system includes a current sensor configured to: (i) remotely sense, at a position external to the electric device, a magnetic field formed by the AC power in the electric device, and (ii) determine, based on the sensed magnetic field, a current of the AC power. The system also includes a voltage sensor configured to, at a position external to the electric device, remotely measure a voltage of the AC power. The system further includes a computing device communicatively coupled to the current sensor and the voltage sensor, the computing device being configured to: (i) determine a phase delay between the current and the voltage, and (ii) determine, based on the phase delay, a power factor of the electric device.

In another example, a method is described for non-invasively determining a power factor of an electric device powered by an alternating current (AC) power. The method includes (i) remotely sensing, at a first position external to the electric device, a magnetic field formed by the AC power in the device, (ii) determining, based on the magnetic field, a current of the AC power, (iii) remotely measuring, at a second position external to the electric device, a voltage of the AC power, (iv)determining a phase delay between the current and the voltage, and (v) determining, based on the phase delay, a power factor of the AC power.

The features, functions, and advantages that have been discussed can be achieved independently in various embodiments or may be combined in yet other embodiments further details of which can be seen with reference to the following description and drawings.

### BRIEF DESCRIPTION OF THE FIGURES

The novel features believed characteristic of the illustrative embodiments are set forth in the appended claims. The illustrative embodiments, however, as well as a preferred mode of use, further objectives and descriptions thereof, will best be understood by reference to the following detailed description of an illustrative embodiment of the present disclosure when read in conjunction with the accompanying drawings, wherein:

FIG. 1 illustrates a simplified block diagram of a system for determining a power factor of an electric device according to an example embodiment.

FIG. 2 illustrates a graph of current and voltage of an AC power that powers an electric device according to an example embodiment.

FIG. 3 illustrates a circuit diagram of a current sensor according to an example embodiment.

FIG. 4 illustrates a simplified block diagram of a voltage sensor configuration according to an example embodiment.

FIG. 5A illustrates a simplified diagram of a voltage senor according to an example embodiment.

FIG. 5B illustrates a side view of the voltage sensor of FIG. 5A.

FIG. 5C illustrates a circuit diagram of the voltage sensor of FIG. 5A.

FIG. 6 illustrates a perspective view of the system with a current sensor in a first position and a voltage sensor in a second position according to an example embodiment.

FIG. 7 illustrates a flowchart of a process for determining a power factor according to an example embodiment.

FIG. 8 illustrates a flowchart of a process for determining a power factor according to an example embodiment.

### DETAILED DESCRIPTION

Disclosed embodiments will now be described more fully hereinafter with reference to the accompanying drawings, in which some, but not all of the disclosed embodiments are shown. Indeed, several different embodiments may be described and should not be construed as limited to the embodiments set forth herein. Rather, these embodiments are described so that this disclosure will be thorough and complete and will fully convey the scope of the disclosure to those skilled in the art.

The systems and methods of the present disclosure provide for determining an indication of how well an electric device is matched to a load powered by the electric device. Within examples, the systems and methods of the present disclosure provide for remotely and non-invasively determining a power factor of the electric device. As used herein, the terms “remotely” and/or “non-invasively” mean using a first device to sense and/or measure one or more conditions related to the operation of a second device without direct physical contact between the first device and the second device. As such, the systems and methods of the present disclosure can determine the power factor without modifying and/or contacting motor circuitry. Example conditions that can be sensed and/or measured include, for instance, a current, a voltage, a magnetic field, a speed, a torque, a sound, a vibration, and/or a temperature relating to the operation of the second device.

The power factor provides a measure of an ability of the electric device to accept energy. For example, when a motor is accepting power from a power line and delivering mechanical power to the load, the power factor is relatively high. Whereas, when the motor is unloaded, the power factor is relatively low. Even though no power is delivered to the load, substantial power is still dissipated by the motor (e.g., by the windings and core of an induction motor).

According to aspects of the present disclosure, the systems and methods described herein provide for determining the power factor based on a phase delay between a current and a voltage of an AC power powering the electric device. For instance, the power factor can be determined based on an equation having the form:

pf=cos(θ) (equation 1)

where pf is the power factor and 0 is the phase delay between the current and the voltage.

The systems and methods of the present disclosure further provide for remotely and non-invasively determining the current and the voltage. For example, the current can be determined based on a sensed magnetic field formed by the AC power flowing through the electric device. The magnetic field generally extends to an environment external to the electric device (e.g., into a space adjacent to a frame of the electric device). Because the magnetic field is proportional to the current of the AC power source, the current can be remotely and non-invasively determined by sensing the magnetic field at a position external to the electric device and without direct contact with the electric device (such as, e.g., internal circuitry of the electric device). Similarly, the systems and methods of the present disclosure provide for remotely and non-invasively measuring the voltage based on the power line supplying the AC power to the electric device. Accordingly, aspects of the present disclosure provide for measuring the current and voltage, and determining the power factor without any modification to circuitry of the electric device.

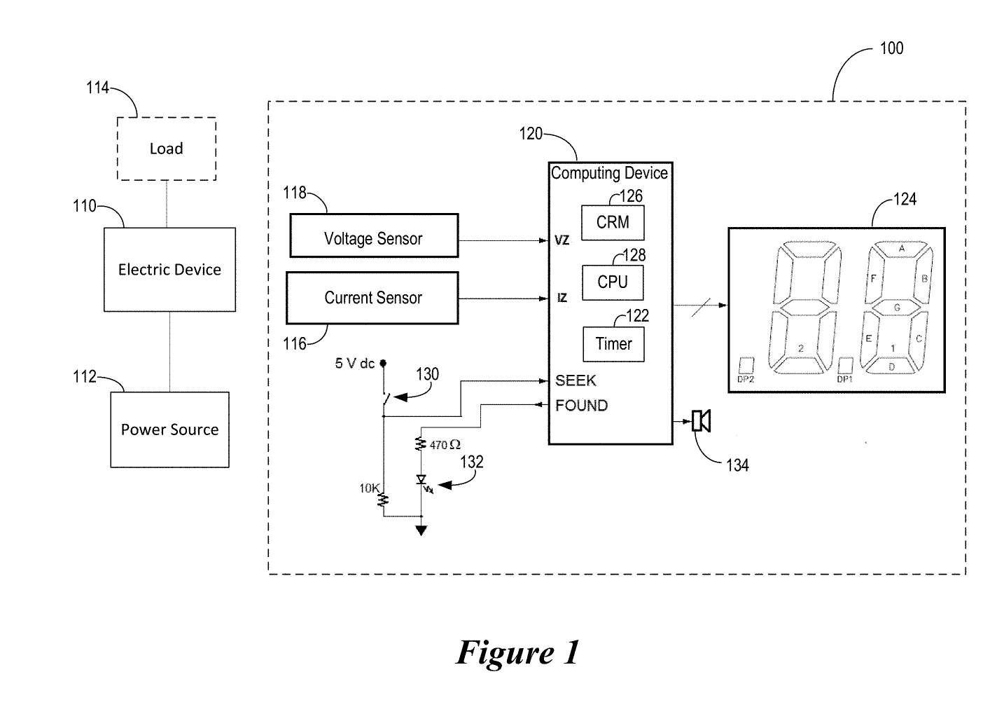

Referring now to FIG. 1, a simplified block diagram of a system 100 for determining a load condition (e.g., a power factor) of an electric device 110 is depicted according to an example embodiment. As shown in FIG. 1, the electric device 110 receives an AC power from an external power source 112. In one example, the power source 112 can be a 120 V_{AC} power supply, and the electric device 110 can be coupled to the power source 112 via a wall outlet. Also, as examples, the electric device 110 can include an induction motor, a transformer, and/or an AC magnetic device. In general, the electric device 110 is configured such that a magnetic field is formed due, at least in part, to the electric device using the AC power to perform a function (e.g., work on a load 114).

For instance, an inductive motor can include a stator surrounding a magnetically polarized rotor. The stator can include a structure on which a conductive winding is wound. The stator and the winding are configured such that a rotating magnetic field is created within the stator when AC current flows through the winding. The rotor can include one or more permanent magnets or may be configured to become magnetized via inductive interaction with the stator's magnetic field (e.g., via conductive coils and/or ferromagnetic materials in the rotor). When the AC power is applied to the winding, the stator's magnetic field can cause the rotor to rotate relative to the stator. The rotor can be coupled to a shaft, which transfers the torque applied to the rotor, and the mechanical energy can then be used to perform work on a load. The rate at which work can be performed using the motor (i.e., the output power of the motor) is related to the torque magnetically applied to the rotor. The torque is proportionate to the strength of the magnetic field imparted on the rotor by the stator's winding. And the strength of the magnetic field is proportionate to the current through the winding, and the number of turns in the winding. The number of turns in the winding is a feature of the winding's geometry, and the current depends on the resistivity of the wire used, the inductance of the winding, and the voltage of the AC power.

As also shown in FIG. 1, the system 100 includes a current sensor 116, a voltage sensor 118, and a computing device 120. The current sensor 116 is configured to, at a position external to the electric device 110, measure a current of the AC power. The voltage sensor 118 configured to, at a position external to the electric device 110, remotely measure a voltage of the AC power. The computing device 120 is communicatively coupled to the current sensor 116 and the voltage sensor 118. The computing device 120 being configured to: (i) determine a phase delay between the current and the voltage, and (ii) determine, based on the phase delay, a power factor of the electric device 110.

In one example, to determine the phase delay, the computing device 120 is configured to determine a first time at which the voltage is zero, determine a second time at which the current is zero, and determine the phase delay based on a difference between the second time and the first time. For instance, the computing device 120 can include a timer 122 and, to determine the phase delay based on the difference between the second time and the first time, the computing device 120 can be configure to: responsive to a determination that the voltage is zero, initiate the timer 122 at the first time and, responsive to a determination that the current is zero, read the timer 122 at the second time. Additional details relating to determinations that the voltage is zero and the current is zero are described in greater detail below.

As shown in FIG. 1, the system 100 can include a display device 124 that is configured to display an indication of the power factor. As examples, the display device 124 can be a light-emitting diode (LED) display and/or a liquid crystal display (LCD). The computing device 120 can store a database including a plurality of records, which each include a respective one of a plurality of phase delay values and a respective one of a plurality of indications of the power factor. The computing device 120 can then identify, using the determined phase delay and the database, the indication of the power factor to display from among the plurality of indications of the power factor.

The computing device 120 may be implemented as a combination of hardware and software elements. The hardware elements may include combinations of operatively coupled hardware components, including microprocessors 128, communication/networking interfaces, memory, signal filters, circuitry, etc. The computing device 120 may be configured to perform operations specified by the software elements, e.g., computer-executable code stored on computer readable medium 126. The computing device 120 may be implemented in any device, system, or subsystem to provide functionality and operation according to the present disclosure. The computing device 120 may be implemented in any number of physical devices/machines.

The physical devices/machines can be implemented by the preparation of integrated circuits or by interconnecting an appropriate network of conventional component circuits, as is appreciated by those skilled in the electrical art(s). The physical devices/machines, for example, may include field programmable gate arrays (FPGA's), application-specific integrated circuits (ASIC's), digital signal processors (DSP's), etc. The physical devices/machines may reside on a wired or wireless network, e.g., LAN, WAN, Internet, cloud, near-field communications, etc., to communicate with each other and/or other systems, e.g., Internet/web resources.

Appropriate software can be readily prepared by programmers of ordinary skill based on the teachings of the example embodiments, as is appreciated by those skilled in the software arts. Thus, the example embodiments are not limited to any specific combination of hardware circuitry and/or software. Stored on one computer readable medium or a combination of computer readable media, the computing systems may include software for controlling the devices and subsystems of the example embodiments, for driving the devices and subsystems of the example embodiments, for enabling the devices and subsystems of the example embodiments to interact with a human user (user interfaces, displays, controls), etc. Such software can include, but is not limited to, device drivers, operating systems, development tools, applications software, etc.

A computer readable medium (CRM) 126 further can include the computer program product(s) for performing all or a portion of the processing performed by the example embodiments. Computer program products employed by the example embodiments can include any suitable interpretable or executable code mechanism, including but not limited to complete executable programs, interpretable programs, scripts, dynamic link libraries (DLLs), applets, etc. The computing device 120 may include, or be otherwise combined with, computer-readable media. Some forms of computer-readable media may include, for example, a hard disk, any other suitable magnetic medium, CD-ROM, CDRW, DVD, any other suitable optical medium, RAM, PROM, EPROM, FLASH-EPROM, any other suitable memory chip or cartridge, a carrier wave, or any other suitable medium from which a computer can read.

The computing device 120 may also include databases for storing data. Such databases may be stored on the computer readable media 126 described above and may organize the data according to any appropriate approach. For examples, the data may be stored in relational databases, navigational databases, flat files, lookup tables, etc. Furthermore, the databases may be managed according to any type of database management software.

The system 100 can also include an input button 130, an indicator light 132, and/or a speaker 134. As will be described in further detail below, the input button 130 can be configured to initiate a process for determining the power factor, the indicator light 132 can be configured to provide visual feedback relating to operation of the system 100, and the speaker 134 can be configured to provide auditory feedback relating to the operation of the system 100.

In the example shown in FIG. 1, the input button 130 is coupled to a “SEEK” input of the computing device 120 and the indicator light is coupled to a “FOUND” output of the computing device 120. Additionally, the input button 130 is configured to selectively conduct a current from a 5 V_{DC} power source to the SEEK input responsive to actuation of the input button 130. Further, a 10 kΩ resistor and a 470 kΩ resistor are coupled in series with the indicator light 132 in the example shown by FIG. 1.

As noted above, the current sensor 116 is configured to remotely sense the current of the AC power in the electric device 110. In one example, the current sensor 116 is configure to (i) remotely sense, at a position external to the electric device 110, a magnetic field formed by the AC power in the electric device 110, and (ii) determine, based on the sensed magnetic field, a current of the AC power. For instance, the current sensor 116 can include a Hall Effect sensor (and/or another type of magnetic field sensor) that senses the magnetic field formed by the AC power in the electric device 110. The sensed magnetic field is proportional to the current of the AC power in the electric device 110. Thus, by remotely sensing the magnetic field formed by the current of the AC power in the electric device 110, the current sensor 116 can remotely measure the current of the AC power used by the electric device 110 to perform work.

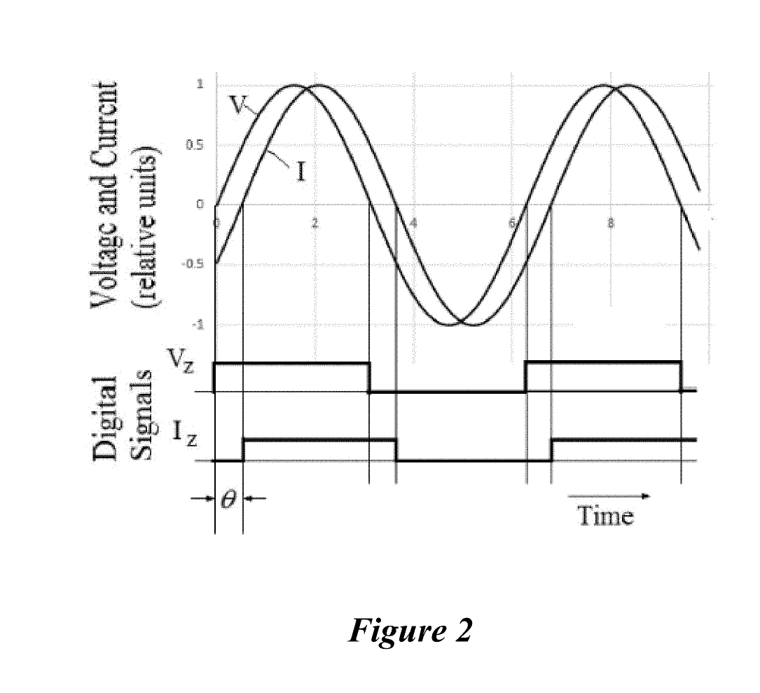

Also, as noted above, the system 100 can determine when the current is zero (i.e., “a current zero-crossing”). In one example, the current sensor 116 can sense the magnetic field, responsively generate a sensor signal based on the sensed magnetic field, and process the signal to produce a digital signal I_{z}, which is representative of the current of the AC power in the electric device 110. For instance, the sensor signal can be passed through a filter that eliminates direct current (“DC”) and attenuates frequencies above a predetermined frequency value (e.g., 1 KHz). The filtered sensor signal can be applied to a comparator to produce the digital signal I_{Z}. The transitions of I_{Z} occur at the current zero-crossings. FIG. 2 depicts a graph of the current of the AC power and the digital signal I_{Z} determined by the current sensor 116 according to an example embodiment.

In one implementation, the current sensor 116 can include a single Hall Effect sensor. In an alternative implementation, the current sensor 116 comprises a plurality of sensors positioned relative to each other such that the measured current is independent of a direction of the sensed magnetic field surrounding the electric device 110. In other words, the current sensor 116 can be omnidirectional magnetic field sensor.

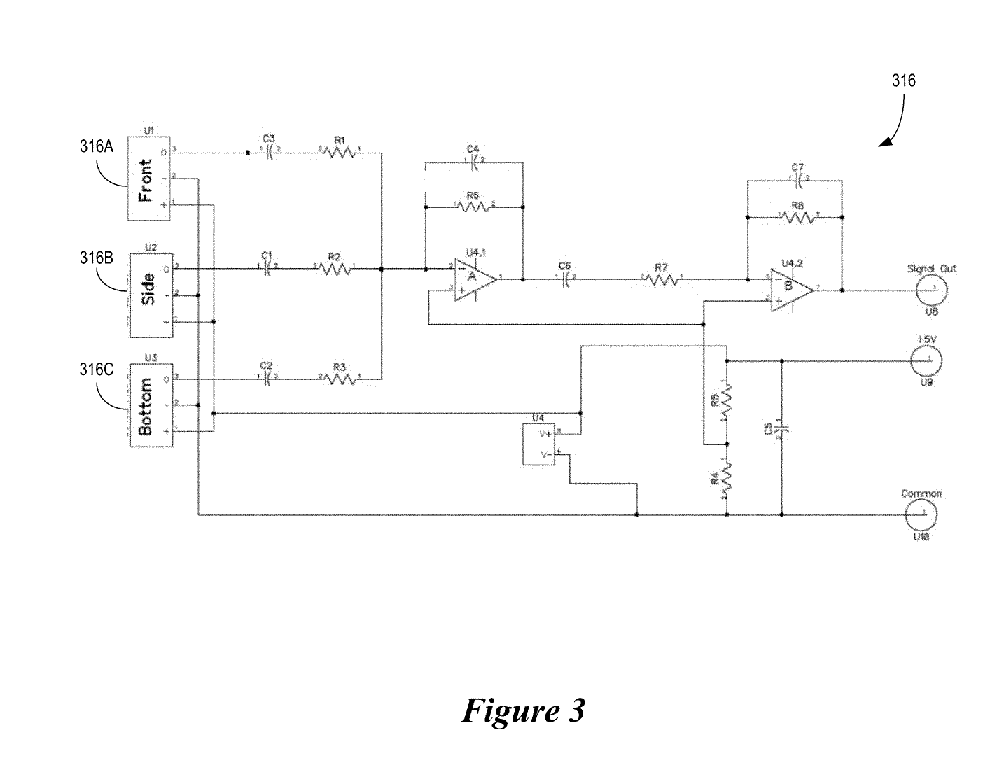

FIG. 3 depicts a circuit diagram for a current sensor 316 according to an example embodiment in which the current sensor 316 measures the current independent of the direction of the magnetic field. As shown in FIG. 3, the current sensor 316 includes a plurality of Hall Effect sensors 316A-316C that are arranged in quadrature relative to each other. For instance, a first sensor 316A is arranged on a front surface of the current sensor 316, a second sensor 316B is arranged on a side surface of the current sensor 316, and a third sensor 316C is arranged on a bottom surface of the current sensor 316 such that the sensors 316A-316C are in quadrature.

As also shown in FIG. 3, the output of each sensor 316A-316C is summed to form the sensor signal representing the sensed magnetic field, which may be a 60 Hz signal. A low pass filter passes the 60 Hz signal representing the magnetic field and blocks high frequency noise. A filter corner frequency of 1 kHz introduces a phase delay of 3.2 degrees. This is compensated by a high pass pole at 3.4 Hz that introduces an approximately equal leading phase.

The voltage sensor 118 can remotely and non-invasively measure the voltage of the AC power so that the computing device 120 can determine when the voltage is zero (i.e., “voltage zero-crossings”). As examples, the voltage sensor 118 can remotely measure the voltage of the AC power by direct contact with the power line supplying the AC power to the electric device, and/or by using a non-contacting capacitive voltage probe.

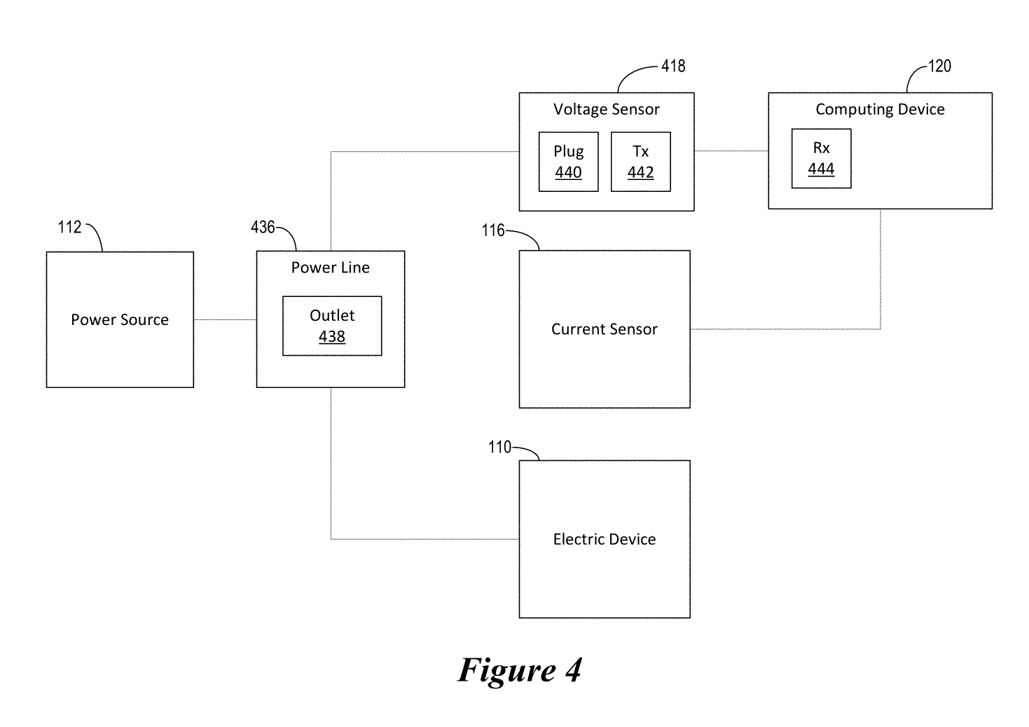

FIG. 4 depicts the voltage sensor 418 directly contacting the power line 436 supplying the AC power to the electric device 110, according to an example embodiment. As shown in FIG. 4, the electric device 110 is coupled to a power line 436, which provides the AC power from the power source 112 to the electric device 110. In one implementation, the coupling between the power line 436 and the electric device 110 can be in the form of a wall outlet 438 and plug 440, respectively.

In FIG. 4, the voltage sensor 418 is also coupled to the power line 436. For instance, the voltage sensor 418 can include the plug 440 that is plugged into the wall outlet 438. In this way, the voltage sensor 418 can directly contact the power line 436 and, thus, measure the voltage of the AC power supplied to the electric device 110. The voltage sensor 418 is communicatively coupled to the computing device 120 via a wired and/or wireless connection such as, for example, the Internet, an intranet, a LAN network, a WAN network, a PSTN network, near-field communications, Bluetooth, combinations thereof, and/or the like.. For example, the voltage sensor 418 can include a transmitter 442 that transmits signals indicative of the measured voltage to a receiver of the computing device 120. In one implementation, the voltage sensor 418 can modulate the signal transmitted by the transmitter 442 according to the voltage of the AC power.

A receiver 444 can demodulate the signal and produce a digital signal V_{Z}, which is synchronized with the voltage of the AC power on the power line. FIG. 2 further depicts the voltage of the AC power and the digital signal V_{Z} determined by the voltage sensor 418 according to an example embodiment.

In a wired implementation, the voltage sensor 418, the current sensor 116, and/or the computing system 120 can be powered by the power source 112 via the power line 436. In a wireless implementation, the voltage sensor 418 can be powered by the power source 112 via the power line 436, whereas the computing device 120 (including the receiver 444) and/or the current senor 116 can be powered by a second power source (not shown) such as, for example, a battery.

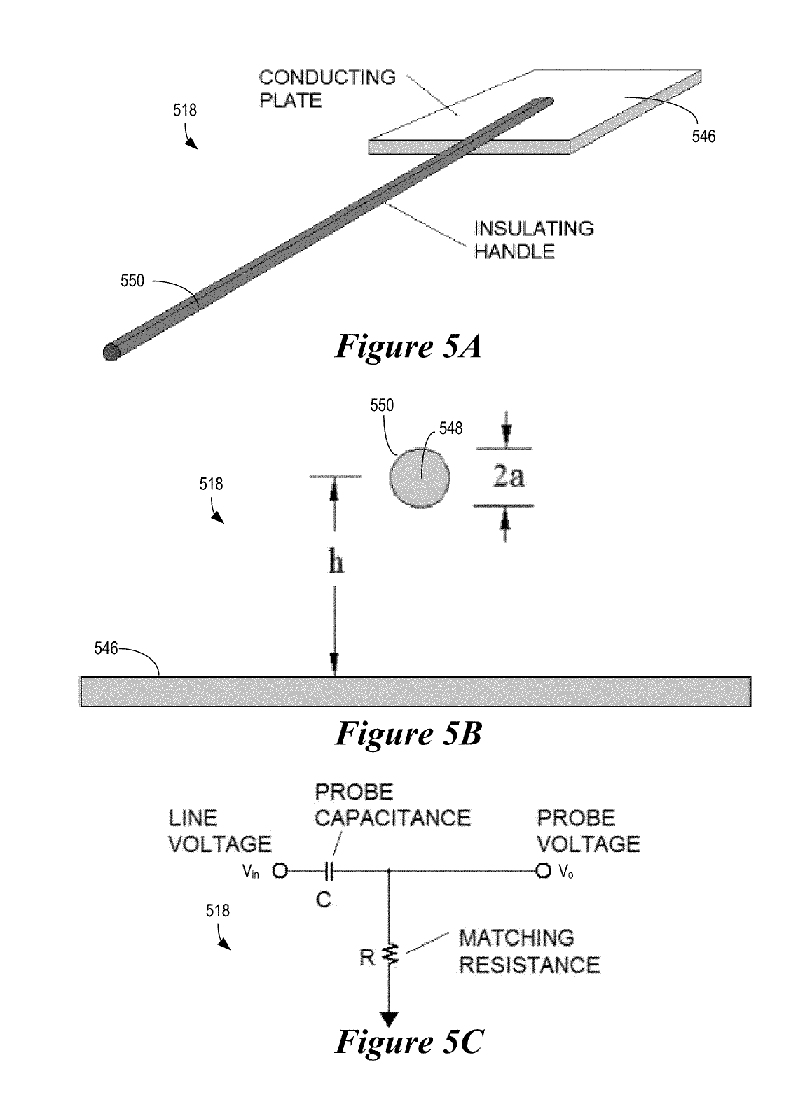

FIGS. 5A-5C depict the voltage sensor 518 according to another example embodiment. In particular, FIG. 5 depicts a capacitive voltage probe 518 that can be used determine the voltage of the AC power. As shown in FIG. 5, the capacitive voltage probe 518 includes a conducting plate 546, a power line wire 548 extending in a plane parallel to a plane of the conducting plate 546, and an insulator 550 enclosing the power line wire 548. The conducting plate 546 and the power line wire 548 form a small capacitance (e.g., on the order of one pF). The probe capacitance is labeled C in FIG. 5C.

Additionally, the circuit shown in FIG. 5C can be analyzed to determine the relationship between the Probe Voltage (Vₒ) and the Line Voltage (Vᵢₙ) according to the following equation:

$$\frac{{V}_{o}}{{V}_{in}} = \frac{jwRC}{1 + jwRC} \qquad ( equation 2 )$$

where C is the probe capacitance and R is a matching resistor. Since ωRC may be significantly less than 1, the denominator in Equation 2 reduces to 1 and, the following equation can be used:

$$\frac{{V}_{o}}{{V}_{in}} = jwRC \qquad ( equation 3 )$$

If the line voltage Vᵢₙ is 120 V_{AC}, the output, Vₒ will lead the line voltage by 90 degrees and be on the order of hundreds of millivolts. The probe plate 546 and the power line wire 548 form a capacitance. The capacitance per meter of a wire above a conducting plane as shown in FIG. 5B can be represented by the following equation:

$$C = \frac{2 π ∈}{ln ( \frac{h}{a} + \sqrt{{( \frac{h}{a} )}^{2} - 1} )} \qquad ( equation 4 )$$

wherein a is a radius of the power line wire 548 and h is the height of the power line wire 548 above the plate 546. As one example, for a 1.8 mm diameter (14 gauge) power line wire 548 that is 5 mm away from the plate 546, the capacitance is 71 pF per meter (1.8 pF per inch). This assumes a dielectric constant of one. A one inch square probe would form about a 2 pF capacitance with the power line 548.

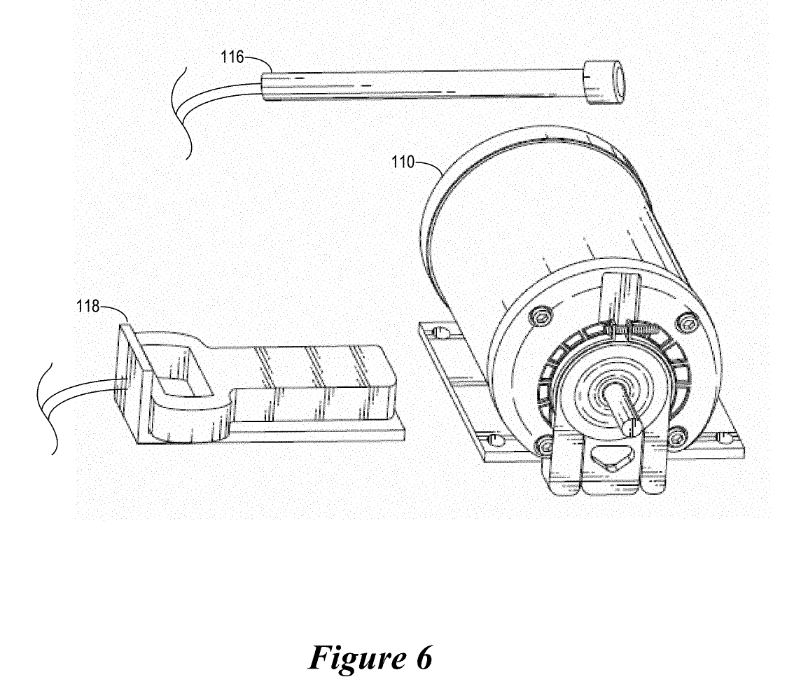

In operation, the power factor can be determined by positioning the current sensor 116, 316 at a first position external to the electric device 110 and positioning the voltage sensor 118, 418, 518 at a second position external to the electric device 110 while the electric device 110 is operating using the AC power supplied by the power source. FIG. 6 depicts a perspective view of the electric device 110 with the current sensor 116 at the first position and the voltage sensor 118 at the second position. In FIG. 6, the first position and the second position are different positions. In an alternative example, the first position and the second position can be the same position.

In one example, the electric device 110 can be a three phase motor, and the system 100 can determine the power factor by considering just one phase. Each phase contributes an equal amount to the torque and motor efficiency. The difference between the phases is related to a time delay and a physical position around the motor axis. The phases have equal power factors, and the motor power factor is equal to the power factor of each individual phase. Because there is a 120 degree phase shift between the phases, this phase delay plus the physical arrangement of the stator coils produces a magnetic field that rotates in space about the axis of the motor. The phase measured by the current sensor 116 may vary with position around the motor axis. Beneficially, when the current sensor 116 includes a plurality of magnetic field sensors, as described above with respect to FIG. 3, the current sensor 116 can measure the magnetic field independent of its direction.

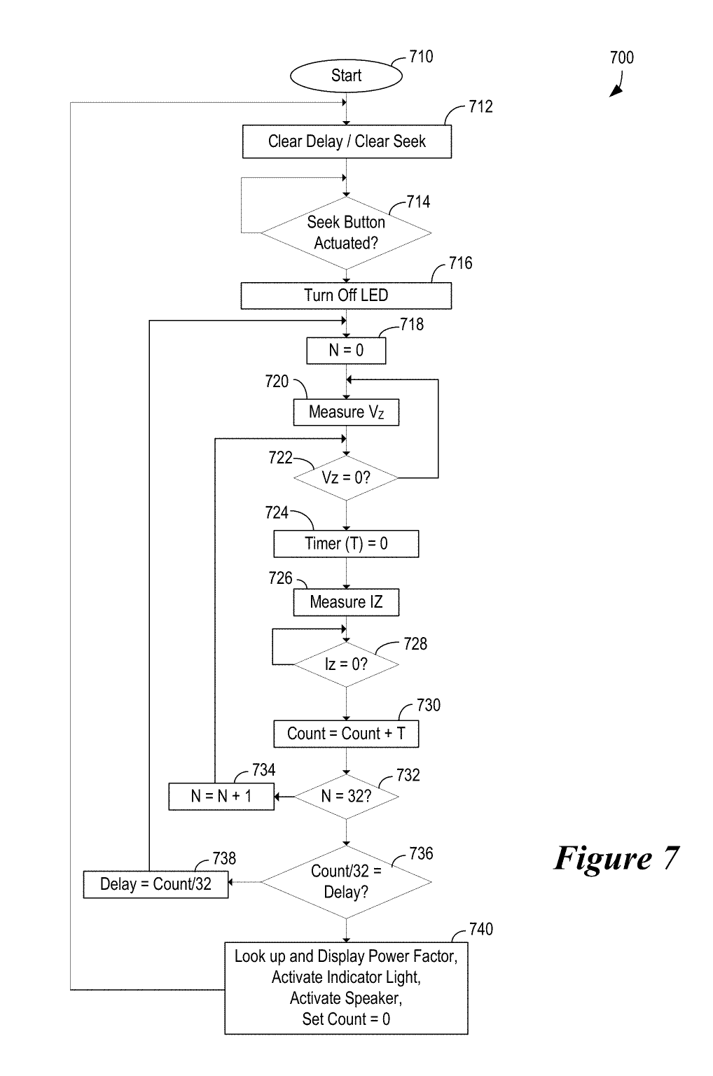

With the current sensor 116 at the first position and the voltage sensor 118 at the second position, a process 700 depicted in FIG. 7 can be carried out to determine the power factor according to one example. As shown in FIG. 7, the process 700 starts at block 710 and proceeds to block 712. At block 712, a value for a Delay parameter is cleared and a value for a Seek parameter corresponding to a state of the input button 130 is cleared. At block 714, the computing device 120 determines whether the input button 130 has been actuated. If the computing device 120 determines that the input button 130 has not been actuated, the computing device 120 repeats the determination at block 712. The process 700 continues to perform the determination at block 714 until the computing device 120 determines that the input button 130 has been actuated.

The process 700 then proceeds to block 716. At block 716, the computing device 120 can turn off the indicator light 132. At block 716, the computing device 120 sets a run counter parameter, N, to a value of 0. At block 718, the system 100 measures the voltage of the AC power source. At block 722, the computing device 120 determines whether the voltage is zero (i.e., whether a voltage zero crossing has occurred). If the computing device 120 determines that the voltage is not equal to 0 at block 722, the process 700 repeats blocks 720 and 722 until the computing system 120 determines that the voltage is 0.

Responsive to the computing device 120 determining that the voltage is zero at block 722, the computing device 120 initiates the timer 122 at block 724. At block 726, the system 100 measures the current of the AC power source. At block 728, the computing device 120 determines whether the current is zero (i.e., whether a current zero crossing has occurred). If the computing device 120 determines that the current is not equal to 0 at block 728, the process 700 repeats blocks 726 and 728 until the computing system 120 determines that the current is 0.

Responsive to the computing device 120 determining that the current is zero at block 728, the computing device 120 reads the timer 122 and increments a Count parameter by the value of the timer 122, T. The value of the timer 122, T, is thus the difference between a second time at which the current was zero at block 728 and a first time at which the voltage was zero at block 722.

At block 732, the computing device 120 determines whether the run counter parameter, N, indicates that the process 700 has been performed a predetermined number of times, M (e.g., M=32 in FIG. 7). If it is determined that process 700 has not been performed M times at block 734, the run counter parameter is incremented at block 734 and the process 700 returns to block 722. If it is determined that the process 700 has been performed M times at block 734, the computing device 120 determines the average Count (i.e., the average delay) by dividing the Count parameter by M (e.g., 32) at block 736. Also, at block 734, the computing device 120 compares the average Count to the value of the Delay parameter to determine whether there is a match at block 736.

If the Delay parameter is not equal to the average Count at block 736, then the computing device sets the Delay parameter to the average Count to be used in a next iteration of the of the process 700 at block 738. If the Delay parameter is equal to the average Count at block 736, then the computing device 120 accesses the database stored in the computing device 120 to look up an indication of the power factor that corresponds to the average of the Count parameter, display 124 the indication of the power factor via the display device, activate the indicator light 132 to indicate that the power factor has been found, and activate the speaker 134 to indicate that the power factor has been found at block 740. Additionally, the computing device 120 can reset the Count parameter to 0 at block 740.

After a first iteration of the predetermined number of times, the Delay parameter is zero because it was cleared at block 712. As such, the process 700 will perform at least two iterations of M times before the average Count can match the Delay parameter at block 736. In the example of FIG. 7, the predetermined number of times, M, to perform the process 700 was 32 times. This can help to reduce noise. Since for a 60 Hz power source, zero-crossings occur every 8.333 milliseconds, the minimum time required to taken and average 32 measurements twice is 0.5333 seconds.

As noted above, the computing device 120 can store the database including a plurality of records, which each include a respective one of a plurality of phase delay values and a respective one of a plurality of indications of the power factor. At block 740, the computing device 120 can access the database to identify, using the average Count as a representation of the determined phase delay, the indication of the power factor to display from among the plurality of indications of the power factor.

In an example, the timer 122 is configured for 32 microseconds per count. Since for 60 Hz, 180 degrees represents a half cycle equal to 8333 microseconds, the number of degrees per count is 0.691 degrees per count. The power factor is calculated using equation 1 above and is displayed for values of phase delay from 0 to 89.9 degrees. That corresponds to counts from 0 to 130. The database can store the correspondence between the counts, degrees, and/or indications of power factor. Thus, by knowing either the count and/or the degree, the computing system 120 can look up and identify the corresponding power factor in the database for display.

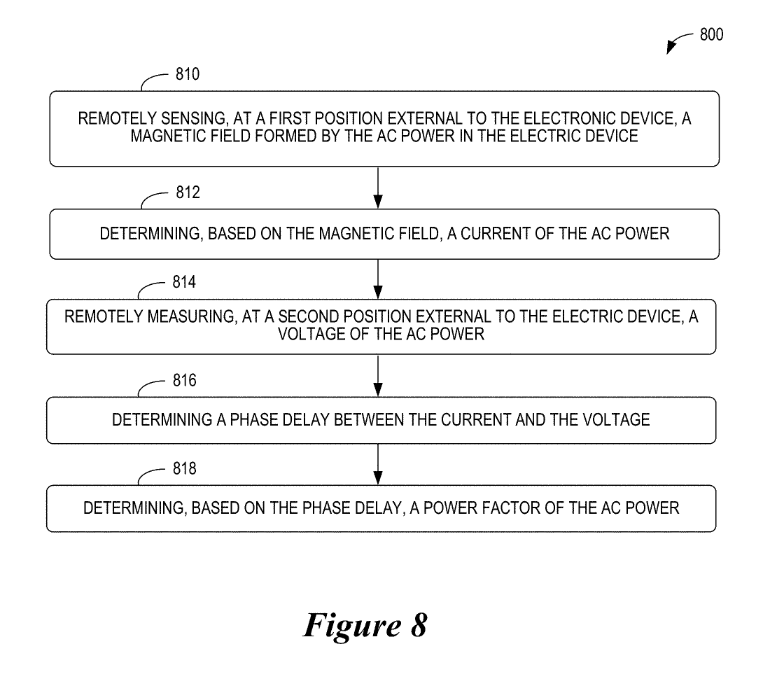

Referring now to FIG. 8, a flowchart for a process 800 of non-invasively determining a power factor of an electric device powered by an alternating current (AC) power is illustrated according to an example embodiment. At block 810, the process 800 includes remotely sensing, at a first position external to the electric device, a magnetic field formed by the AC power in the electric device. At block 812, the process 800 includes determining, based on the magnetic field, a current of the AC power. At block 814, the process 800 includes remotely measuring, at a second position external to the electric device, a voltage of the AC power. At block 816, the process 800 includes determining a phase delay between the current and the voltage. At block 818, the process 800 includes determining, based on the phase delay, a power factor of the AC power.

The systems and methods of the present disclosure provide a number of advantages over other systems. As one example, a factor correction may be conventionally performed by placing a compensating capacitor in parallel with the motor. Since capacitor current leads voltage, the delay of the current drawn from the power line can be reduced resulting in a high power factor as seen by the power line. The intrinsic motor power factor does not change. The current drawn from the power line is the combination of the motor current and the current of the compensating capacitor. The motor's intrinsic power factor, without the compensating effect of the capacitor, depends on the motor current. The motor current determines the magnetic field. Since the systems and methods of the present disclosure use the motor magnetic field to determine current, the systems and methods of the present disclosure measure the intrinsic power factor, not the capacitor compensated power factor. Motor operating parameters, such as efficiency, depend on the intrinsic power factor, not on the capacitor compensated power factor. Additionally, for example, using the motor magnetic field to determine the current zero-crossings and then determining power factor by measuring the delay between the current and voltage zero-crossings is efficient and accurate.

Any of the blocks shown in FIGS. 7-8 may represent a module, a segment, or a portion of program code, which includes one or more instructions executable by a processor for implementing specific logical functions or steps in the process. The program code may be stored on any type of computer readable medium or data storage, for example, such as a storage device including a disk or hard drive. Further, the program code can be encoded on a computer-readable storage media in a machine-readable format, or on other non-transitory media or articles of manufacture. The computer readable medium may include non-transitory computer readable medium or memory, for example, such as computer-readable media that stores data for short periods of time like register memory, processor cache and Random Access Memory (RAM). The computer readable medium may also include non-transitory media, such as secondary or persistent long term storage, like read only memory (ROM), optical or magnetic disks, compact-disc read only memory (CD-ROM), for example. The computer readable media may also be any other volatile or non-volatile storage systems. The computer readable medium may be considered a tangible computer readable storage medium, for example.

In some instances, components of the devices and/or systems described herein may be configured to perform the functions such that the components are actually configured and structured (with hardware and/or software) to enable such performance. Example configurations then include one or more processors executing instructions to cause the system to perform the functions. Similarly, components of the devices and/or systems may be configured so as to be arranged or adapted to, capable of, or suited for performing the functions, such as when operated in a specific manner.

The power factor determined by the systems and methods of the present disclosure can be used to reduce and/or mitigate inefficient energy usage by the electric device according to an example embodiment. For example, the systems and methods of the present disclosure can be used as a load sensor for determining a metric indicative of a load condition of an electric motor and combined with the systems and methods disclosed in U.S. Pat. No. 9,425,728, filed Nov. 3, 2015, the contents of which is hereby incorporated by reference in its entirety.

The description of the different advantageous arrangements has been presented for purposes of illustration and description, and is not intended to be exhaustive or limited to the embodiments in the form disclosed. Many modifications and variations will be apparent to those of ordinary skill in the art. Further, different advantageous embodiments may describe different advantages as compared to other advantageous embodiments. The embodiment or embodiments selected are chosen and described in order to explain the principles of the embodiments, the practical application, and to enable others of ordinary skill in the art to understand the disclosure for various embodiments with various modifications as are suited to the particular use contemplated.

What is claimed is:

1. A system for determining a power factor of an electric device powered by an alternating current (AC) power, the system comprising:
a current sensor configured to:
remotely sense, at a position external to the electric device, a magnetic field formed by the AC power in the electric device, and
determine, based on the sensed magnetic field, a current of the AC power;
a voltage sensor configured to, at a position external to the electric device, remotely measure a voltage of the AC power; and
a computing device communicatively coupled to the current sensor and the voltage sensor, the computing device being configured to:
determine a phase delay between the current and the voltage, and
determine, based on the phase delay, a power factor of the electric device.

2. The system of claim 1, wherein the electric device is at least one of an induction motor, a transformer, or an AC magnetic device.

3. The system of claim 1, wherein the current sensor comprises a Hall Effect sensor.

4. The system of claim 1, wherein the current sensor comprises a plurality of sensors positioned relative to each other such that the measured current is independent of a direction of the sensed magnetic field.

5. The system of claim 1, wherein the voltage sensor comprises capacitive voltage probe.

6. The system of claim 5, wherein the capacitive voltage probe comprises:
a conducting plate;
a power line wire extending in a plane parallel to a plane of the conducting plate; and
an insulator enclosing the power line wire.

7. The system of claim 1, wherein the voltage sensor is in direct contact with a power line, which supplies the AC power to the electric device.

8. The system of claim 7, wherein the voltage sensor comprises:
a wall plug configured to be plugged into a wall output;
a transmitter coupled to the wall plug and configure to wirelessly transmit a signal, which is modulated by a voltage of the power line; and
a receiver coupled to the computing device and configured to receive the signal transmitted by the transmitter.

9. The system of claim 1, wherein, to determine the phase delay, the computing device is configured to:
determine a first time at which the voltage is zero;
determine a second time at which the current is zero; and
determine the phase delay based on a difference between the second time and the first time.

10. The system of claim 9, wherein the computing device comprises a timer, and
wherein, to determine the phase delay based on the difference between the second time and the first time, the computing device is configure to:
responsive to a determination that the voltage is zero, initiate the timer at the first time and
responsive to a determination that the current is zero, read the timer at the second time.

11. The system of claim 1, further comprising a display device configured to display an indication of the power factor.

12. The system of claim 11, wherein the computing system is further configured to:
store a database including a plurality of records, which each include a respective one of a plurality of phase delay values and a respective one of a plurality of indications of the power factor; and
identify, using the determined phase delay and the database, the indication of the power factor to display from among the plurality of indications of the power factor.

13. A method for non-invasively determining a power factor of an electric device powered by an alternating current (AC) power, the method comprising:
remotely sensing, at a first position external to the electric device, a magnetic field formed by the AC power in the electric device;
determining, based on the magnetic field, a current of the AC power;
remotely measuring, at a second position external to the electric device, a voltage of the AC power;
determining a phase delay between the current and the voltage; and
determining, based on the phase delay, a power factor of the AC power.

14. The method of claim 13, further comprising:
positioning a current sensor at the first position, wherein the current sensor does not contact the electric device at the first position; and
positioning a voltage sensor at the second position, wherein the voltage sensor does not contact the electric device at the second position.

15. The method of claim 13, determining the phase delay comprises:
determining a first time at which the voltage is zero;
determining a second time at which the current is zero; and
determining the phase delay based on a difference between the second time and the first time.

16. The method of claim 13, wherein remotely measuring the voltage of the AC power comprises coupling a voltage sensor to a wall outlet, which supplies the AC power to the electric device.

17. The method of claim 13, wherein sensing the magnetic field comprises:
sensing the magnetic field using a plurality of sensors;
providing, from each sensor, a respective output indicative of the magnetic field sensed by the sensor; and
summing the outputs of the plurality of sensors.

18. The method of claim 13, further comprising a displaying, on a display device, an indication of the power factor.

19. The method of claim 13, wherein the electric device is at least one of an induction motor, a transformer, or an AC magnetic device.

20. The method of claim 13, wherein remotely sensing the magnetic field is performed using a Hall Effect sensor.
